(19) United States
(12) Patent Application Publication
(10) Pub. No.: US 2024/0188331 A1
(43) Pub. Date: Jun. 6, 2024

(54) DISPLAY PANEL AND DISPLAY DEVICE

(71) Applicant: LG Display Co., Ltd., Seoul (KR)

(72) Inventors: HongRak CHOI, Paju-si (KR); JuHeyuck BAECK, Paju-si (KR); Dohyung LEE, Paju-si (KR); Younghyun KO, Paju-si (KR); ChanYong JEONG, Paju-si (KR)

(73) Assignee: LG Display Co., Ltd., Seoul (KR)

(21) Appl. No.: 18/376,565

(22) Filed: Oct. 4, 2023

(30) Foreign Application Priority Data
Dec. 5, 2022 (KR) 10-2022-0167282

(51) Int. Cl. H10K 59/121; G09G 3/32

(52) U.S. Cl. CPC H10K 59/1216; G09G 3/32; H10K 59/1213; G09G 2300/0842

(57) ABSTRACT

A display panel includes a substrate, a first storage capacitor electrode disposed on the substrate, a buffer layer disposed on the first storage capacitor electrode, an active layer disposed on the buffer layer and including a first area, a second area, and a channel area disposed between the first area and the second area, a gate insulation film disposed on the active layer, a gate electrode disposed on the gate insulation film and overlapping with the channel area, an inter-layer insulation film disposed on the gate electrode, and a metal layer disposed on the inter-layer insulation film, wherein the first area and the second area of the active layer are conductive areas, and wherein a conductive auxiliary layer overlapping with at least a portion of each of the first area and the second area and not overlapping with the channel area is included on the substrate, thereby mitigating the step in the area where the storage capacitor electrodes are disposed to prevent a short circuit.

### CROSS-REFERENCE TO RELATED APPLICATION

This application claims the priority of Korean Patent Application No. 10-2022-0167282, filed on Dec. 5, 2022, which is hereby incorporated by reference in its entirety.

### BACKGROUND

### Field of the Disclosure

The present disclosure relates to a display panel and a display device.

### Description of the Background

Thin film transistors are widely used as switching devices or driving devices in the field of electronic devices.

In particular, thin film transistors are widely used as driving or switching devices in display devices such as liquid crystal display devices or organic light emitting display devices because they may be manufactured on glass or plastic substrates.

The storage capacitor plays a role to maintain the voltage difference between both the terminals during a predetermined frame time, allowing the subpixel SP to emit light during the predetermined frame time.

However, these storage capacitors are facing capacity issues and suffer from a short circuit due to the stacking of multiple electrodes.

### SUMMARY

Accordingly, the present disclosure is directed to a display panel and a display device that substantially obviate one or more of problems due to limitations and disadvantages described above.

More specifically, the present disclosure is to provide a display panel and a display device capable of increasing the capacity of the storage capacitor while mitigating the step in the area where storage capacitor electrodes are disposed to prevent a short circuit, thereby saving costs and enhancing yield.

In addition, the present disclosure is to provide a display panel and a display device capable of implementing high resolution, high response speed, and low power by increasing the capacity of the storage capacitor.

Further, the present disclosure is to provide a display panel and a display device in which an electrode formed of an oxide semiconductor material and an active layer may easily be rendered conductive.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display panel includes a substrate, a first storage capacitor electrode disposed on the substrate, a buffer layer disposed on the first storage capacitor electrode, an active layer disposed on the buffer layer and including a first area, a second area, and a channel area disposed between the first area and the second area, a gate insulation film disposed on the active layer, a gate electrode disposed on the gate insulation film and overlapping with the channel area, an inter-layer insulation film disposed on the gate electrode, and a metal layer disposed on the inter-layer insulation film, wherein the first area and the second area of the active layer are conductive areas, and wherein a conductive auxiliary layer overlapping with at least a portion of each of the first area and the second area and not overlapping with the channel area is included on the substrate.

In another aspect of the present disclosure, a display device includes a first storage capacitor electrode disposed on a substrate, a buffer layer disposed on the first storage capacitor electrode, an active layer disposed on the buffer layer and including a first area, a second area, and a channel area disposed between the first area and the second area, a gate insulation film disposed on the active layer, a gate electrode disposed on the gate insulation film and overlapping with the channel area, an inter-layer insulation film disposed on the gate electrode, and a metal layer disposed on the inter-layer insulation film, wherein the first area and the second area of the active layer are conductive areas, wherein a conductive auxiliary layer overlapping with at least a portion of each of the first area and the second area is included on the substrate, and wherein the gate electrode is disposed in an area between portions of the conductive auxiliary layer.

According to various aspects of the present disclosure, there may be provided a display panel and a display device capable of increasing the capacity of the storage capacitor while mitigating the step in the area where storage capacitor electrodes are disposed to prevent a short circuit, thereby saving costs and enhancing yield.

According to various aspects of the present disclosure, there may be provided a display panel and a display device capable of implementing high resolution, high response speed, and low power by increasing the capacity of the storage capacitor.

According to various aspects of the present disclosure, there may be provided a display panel and a display device in which an electrode formed of an oxide semiconductor material and an active layer may easily be rendered conductive.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description, taken in conjunction with the accompanying drawings, in which:

FIG. 1 is a view illustrating a system configuration of a display device according to aspects of the disclosure;

FIG. 2 is an equivalent circuit diagram illustrating a subpixel of a display device according to aspects of the disclosure;

FIG. 3 is another equivalent circuit diagram illustrating a subpixel of a display device according to aspects of the disclosure;

FIGS. 4A and 4B are views illustrating a light shield (LS) in a subpixel of a display device according to aspects of the disclosure;

FIG. 5 is a view schematically illustrating a cross-sectional structure of one subpixel area of a display device according to aspects of the disclosure;

FIG. 6 is a plan view illustrating a pad area of a subpixel according to aspects of the disclosure;

FIG. 7 is a cross-sectional view taken along line A-B of FIG. 6;

FIG. 8 is a cross-sectional view illustrating a structure in which a metal layer and a storage capacitor are connected according to aspects of the disclosure;

FIG. 9 is a cross-sectional view illustrating a structure of a storage capacitor according to aspects of the disclosure;

FIGS. 10 and 11 are cross-sectional views illustrating various positions of a conductive auxiliary layer according to aspects of the disclosure; and

FIG. 12 is a view illustrating an arrangement relationship between a conductive auxiliary layer and a gate electrode according to aspects of the disclosure.

FIG. 13 is a view illustrating a transistor and a storage capacitor included in a display panel according to aspects of the disclosure.

### DETAILED DESCRIPTION

In the following description of examples or aspects of the disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the disclosure, detailed descriptions of well-known functions and components incorporated herein will be omitted when it is determined that the description may make the subject matter in some aspects of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(a),” or “(b)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only may the first element “be directly connected or coupled to” or “directly contact or overlap with” the second element, but a third element may also be “interposed” between the first and second elements, or the first and second elements may “be connected or coupled to”, “contact or overlap with”, etc. each other via a fourth element. Here, the second element may be included in at least one of two or more elements that “are connected or coupled to”, “contact or overlap with,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e. g., level, range, etc.) include a tolerance or error range that may be caused by various factors e. g., process factors, internal or external impact, noise, etc.) even when a relevant description is not specified. Further, the term “may” fully encompasses all the meanings of the term “may.”

Hereinafter, various aspects of the disclosure are described in detail with reference to the accompanying drawings.

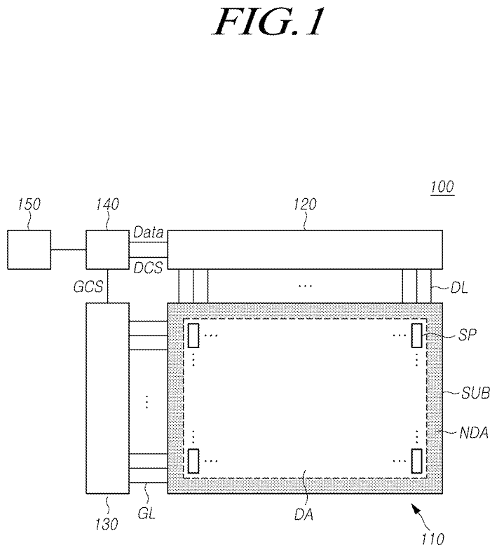

FIG. 1 is a view illustrating a system configuration of a display device 100 according to aspects of the disclosure.

Referring to FIG. 1, a display device 100 according to aspects of the disclosure may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate SUB and signal lines, such as a plurality of data lines DL and a plurality of gate lines GL disposed on the substrate SUB. The display panel 110 may include a plurality of subpixels SP connected to the plurality of data lines DL and the plurality of gate lines GL.

The display panel 110 may include a display area DA in which images are displayed and a non-display area NDA which is positioned outside of the display area DA and where no image is displayed. In the display panel 110, a plurality of subpixels SP for displaying images may be disposed in the display area DA, and the driving circuits 120, 130, and 140 may be electrically connected to or disposed in the non-display area NDA. Further, pad units for connection of integrated circuits or a printed circuit may be disposed in the non-display area NDA.

The data driving circuit 120 is a circuit for driving the plurality of data lines DL, and may supply data signals to the plurality of data lines DL. The gate driving circuit 130 is a circuit for driving the plurality of gate lines GL, and may supply gate signals to the plurality of gate lines GL. The controller 140 may supply a data control signal DCS to the data driving circuit 120 to control the operation timing of the data driving circuit 120. The controller 140 may supply a gate control signal GCS for controlling the operation timing of the gate driving circuit 130 to the gate driving circuit 130.

The controller 140 may control to start scanning according to a timing implemented in each frame, convert input image data input from the outside into image data Data suited for the data signal format used in the data driving circuit 120, supply the image data Data to the data driving circuit 120, and control data driving to proceed at an appropriate time according to the scanning timing.

To control the gate driving circuit 130, the controller 140 may output various gate control signals GCS including a gate start pulse GSP, a gate shift clock GSC, and a gate output enable signal GOE.

To control the data driving circuit 120, the controller 140 may output various data control signals DCS including, e.g., a source start pulse SSP, a source sampling clock SSC, and a source output enable signal SOE.

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit (SDICs).

For example, each source driver integrated circuit (SDIC) may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap with the subpixels SP or to overlap with all or some of the subpixels SP.

When a specific gate line GL is opened by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The display device 100 according to aspects of the disclosure may be a display including a backlight unit, such as a liquid crystal display, or may be a self-emission display, such as an organic light emitting diode (OLED) display, a quantum dot display, or a micro light emitting diode (LED) display.

If the display device 100 according to aspects of the disclosure is an OLED display, each subpixel SP may include an organic light emitting diode (OLED), which by itself emits light, as the light emitting element. If the display device 100 according to aspects of the disclosure is a quantum dot display, each subpixel SP may include a light emitting element formed of a quantum dot, which is a self-luminous semiconductor crystal. If the display device 100 according to aspects of the disclosure is a micro LED display, each subpixel SP may include a micro LED, which is self-emissive and formed of an inorganic material, as the light emitting element.

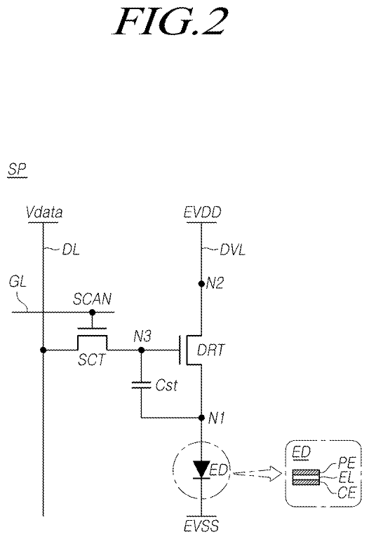

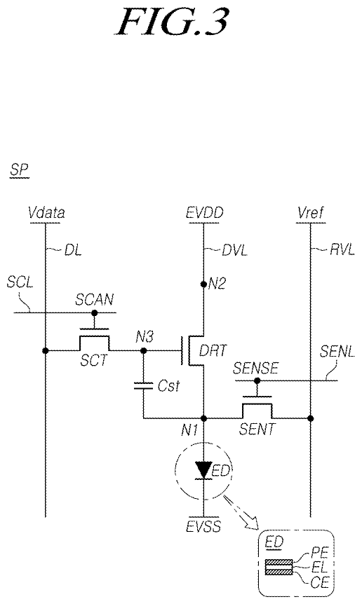

FIG. 2 illustrates an equivalent circuit of a subpixel SP of a display device 100 according to aspects of the disclosure, and FIG. 3 illustrates another equivalent circuit of a subpixel SP of the display device 100 according to aspects of the disclosure.

Referring to FIG. 2, each of a plurality of subpixels SP disposed on a display panel 110 of a display device 100 according to aspects of the disclosure may include a light emitting element ED, a driving thin film transistor DRT, a scanning thin film transistor SCT, and a storage capacitor Cst.

Referring to FIG. 2, the light emitting element ED may include a pixel electrode PE and a common electrode CE and may include a light emitting layer EL positioned between the pixel electrode PE and the common electrode CE.

The pixel electrode PE of the light emitting element ED may be an electrode disposed in each subpixel SP, and the common electrode CE may be an electrode commonly disposed in all the subpixels SP. Here, the pixel electrode PE may be an anode electrode, and the common electrode CE may be a cathode electrode. Conversely, the pixel electrode PE may be a cathode electrode, and the common electrode CE may be an anode electrode.

For example, the light emitting element ED may be an organic light emitting diode (OLED), a light emitting diode (LED), or a quantum dot light emitting element.

The driving thin film transistor DRT is a thin film transistor for driving the light emitting element ED, and may include a first node N1, a second node N2, and a third node N3.

The first node N1 of the driving thin film transistor DRT may be the source node (source electrode) or the drain node (drain electrode) of the driving thin film transistor DRT, and may be electrically connected to the pixel electrode PE of the light emitting element ED. The second node N2 of the driving thin film transistor DRT may be the drain node (drain electrode) or the source node (source electrode) of the driving thin film transistor DRT and be electrically connected to a driving voltage line DVL supplying the driving voltage EVDD. The third node N3 of the driving thin film transistor DRT may be the gate node (gate electrode) of the driving thin film transistor DRT and be electrically connected to the source node or the drain node of the scanning thin film transistor SCT.

The scanning thin film transistor SCT may be controlled by a scanning gate signal SCAN, which is a type of gate signal, and may be connected between the third node N3 of the driving thin film transistor DRT and the data line DL. In other words, the scanning thin film transistor SCT may be turned on or off according to the scanning gate signal SCAN supplied from the scanning gate line SCL, which is a type of the gate line GL, controlling the connection between the data line DL and the third node N3 of the driving thin film transistor DRT.

The scanning thin film transistor SCT may be turned on by the scanning gate signal SCAN having a turn-on level voltage and transfer the data voltage Vdata supplied from the data line DL to the third node N3 of the driving thin film transistor DRT.

If the scanning thin film transistor SCT is an n-type thin film transistor, the turn-on level voltage of the scanning gate signal SCAN may be a high level voltage. If the scanning thin film transistor SCT is a p-type thin film transistor, the turn-on level voltage of the scanning gate signal SCAN may be a low level voltage.

The storage capacitor Cst may be electrically connected between the third node N3 and first node N1 of the driving thin film transistor DRT. The storage capacitor Cst is charged with the quantity of electric charge corresponding to the voltage difference between both ends thereof and serves to maintain the voltage difference between both ends for a predetermined frame time. Accordingly, during the predetermined frame time, the corresponding subpixel SP may emit light.

Referring to FIG. 3, each of the plurality of subpixels SP disposed on the display panel 110 of the display device 100 according to aspects of the disclosure may further include a sensing thin film transistor SENT.

The sensing thin film transistor SENT may be controlled by a sensing gate signal SENSE, which is a type of gate signal, and may be connected between the first node N1 of the driving thin film transistor DRT and the reference voltage line RVL. In other words, the sensing thin film transistor SENT may be turned on or off according to the sensing gate signal SENSE supplied from the sensing gate line SENL, which is another type of the gate line GL, controlling the connection between the reference voltage line RVL and the first node N1 of the driving thin film transistor DRT.

The sensing thin film transistor SENT may be turned on by the sensing gate signal SENSE having a turn-on level voltage and transfer a reference voltage Vref supplied from the reference voltage line RVL to the first node N1 of the driving thin film transistor DRT.

The sensing thin film transistor SENT may be turned on by the sensing gate signal SENSE having a turn-on level voltage, transferring the voltage of the first node N1 of the driving thin film transistor DRT to the reference voltage line RVL.

If the sensing thin film transistor SENT is an n-type thin film transistor, the turn-on level voltage of the sensing gate signal SENSE may be a high level voltage. If the sensing thin film transistor SENT is a p-type thin film transistor, the turn-on level voltage of the sensing gate signal SENSE may be a low level voltage.

The function in which the sensing thin film transistor SENT transfers the voltage of the first node N1 of the driving thin film transistor DRT to the reference voltage line RVL may be used upon driving to sense the characteristic value of the subpixel SP. In this case, the voltage transferred to the reference voltage line RVL may be a voltage for calculating the characteristic value of the subpixel SP or a voltage reflecting the characteristic value of the subpixel SP.

Each of the driving thin film transistor DRT, the scanning thin film transistor SCT, and the sensing thin film transistor SENT may be an n-type thin film transistor or a p-type thin film transistor. In the disclosure, for convenience of description, each of the driving thin film transistor DRT, the scanning thin film transistor SCT, and the sensing thin film transistor SENT is an n-type thin film transistor.

The storage capacitor Cst is not a parasitic capacitor (e.g., Cgs or Cgd) which is an internal capacitor existing between the gate node and the source node (or drain node) of the driving thin film transistor DRT, but may be an external capacitor intentionally designed outside the driving thin film transistor DRT.

The scanning gate line SCL and the sensing gate line SENL may be different gate lines GL. In this case, the scanning gate signal SCAN and the sensing gate signal SENSE may be separate gate signals, and the on-off timings of the scanning thin film transistor SCT and the on-off timings of the sensing thin film transistor SENT in one subpixel SP may be independent. In other words, the on-off timings of the scanning thin film transistor SCT and the on-off timings of the sensing thin film transistor SENT in one subpixel SP may be the same or different.

Alternatively, the scanning gate line SCL and the sensing gate line SENL may be the same gate line GL. In other words, the gate node of the scanning thin film transistor SCT and the gate node of the sensing thin film transistor SENT in one subpixel SP may be connected with one gate line GL. In this case, the scanning gate signal SCAN and the sensing gate signal SENSE may be the same gate signals, and the on-off timings of the scanning thin film transistor SCT and the on-off timings of the sensing thin film transistor SENT in one subpixel SP may be the same.

The structures of the subpixel SP shown in FIGS. 2 and 3 are merely examples, and various changes may be made thereto, e.g., such as including one or more thin film transistors or one or more capacitors.

Although the subpixel structure is described in connection with FIGS. 2 and 3 under the assumption that the display device 100 is a self-emission display device, if the display device 100 is a liquid crystal display, each subpixel SP may include a thin film transistor and a pixel electrode.

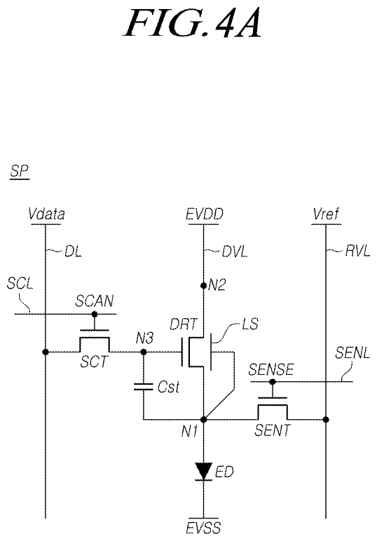

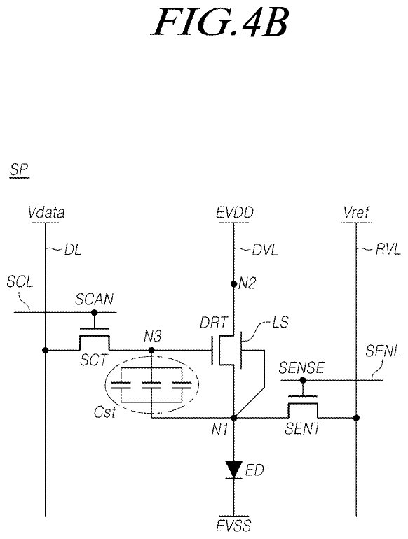

FIGS. 4A and 4B are views illustrating a light shield LS in a subpixel SP of a display device 100 according to aspects of the disclosure.

Referring to FIGS. 4A and 4B, in the subpixel SP of the display device 100 according to aspects of the disclosure, the driving thin film transistor DRT may have intrinsic characteristics, such as threshold voltage and mobility. When the intrinsic characteristics of the driving thin film transistor DRT change, the current driving capability (current supply capability) of the driving thin film transistor DRT changes, and thus the light emitting characteristics of the corresponding subpixel SP may also change.

The device characteristics (e.g., threshold voltage, mobility, etc.) of the driving thin film transistor DRT may change as the driving time of the driving thin film transistor DRT elapses. Further, when light is radiated to the driving thin film transistor DRT, particularly to the channel area of the driving thin film transistor DRT, the device characteristics (e.g., threshold voltage, mobility, etc.) of the driving thin film transistor DRT may change.

Therefore, as illustrated in FIGS. 4A and 4B, to reduce a change in device characteristics (e.g., a change in threshold voltage, change in mobility, etc.) of the driving thin film transistor DRT, a light shield LS may be formed near the driving thin film transistor DRT. For example, the light shield LS may be formed under the channel area of the driving thin film transistor DRT.

Meanwhile, not only does it block light, but the light shield LS may also serve as a body of the driving thin film transistor DRT by being formed under the channel area of the driving thin film transistor DRT.

A body effect may occur in the driving thin film transistor DRT. To reduce the body effect, the light shield LS serving as the body of the driving thin film transistor DRT may be electrically connected to the first node N1. Here, the first node N1 of the driving thin film transistor DRT may be the source node of the driving thin film transistor DRT.

Meanwhile, the light shield LS may be disposed not only under the channel area of the driving thin film transistor DRT, but also under the channel area of another thin film transistor (e.g., SCT or SENT).

In the display area DA of the display panel 110 according to aspects of the disclosure, thin film transistors DRT, SCT, and SENT may be disposed in each subpixel SP. When the gate driving circuit 130 is formed in a gate in panel (GIP) type in the non-display area NDA of the display panel 110 according to aspects of the disclosure, the plurality of thin film transistors included in the GIP-type gate driving circuit 130 may be disposed in the non-display area NDA of the display panel 110.

As shown in FIGS. 4A and 4B, a storage capacitor Cst may be disposed in the subpixel SP of the display panel 110 according to aspects of the disclosure.

For example, as shown in FIG. 4A, one storage capacitor Cst may be connected to the driving transistor DRT, or as shown in FIG. 4B, at least two storage capacitors Cst may be connected in parallel.

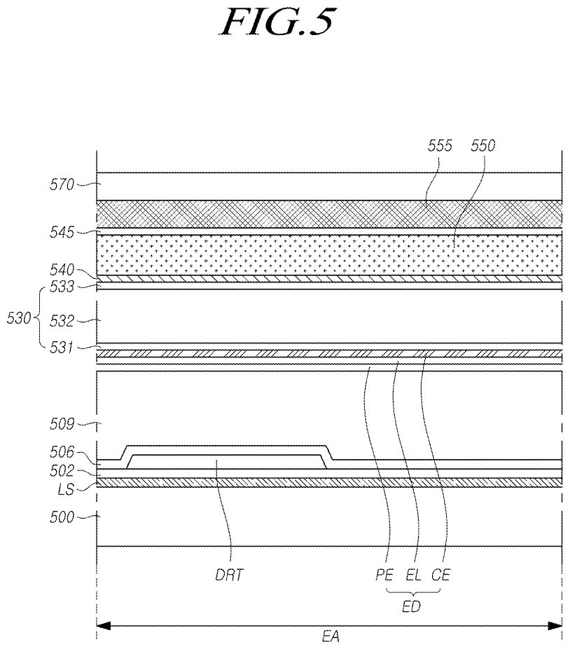

FIG. 5 is a view schematically illustrating a cross-sectional structure of one subpixel area of a display device according to aspects of the disclosure.

Referring to FIG. 5, the display device 100 according to aspects of the disclosure may include at least one thin film transistor disposed on a substrate 500 and a light emitting element ED disposed on the thin film transistor.

The thin film transistor shown in FIG. 5 may be the driving transistor DRT, and the light emitting element ED may be electrically connected to the driving transistor DRT.

However, the types of thin film transistors of aspects of the disclosure are not limited thereto.

Specifically, a light shield LS may be disposed on the substrate 500.

A buffer layer 502 may be disposed on the light shield LS.

In FIG. 5, the buffer layer 502 has a single-layer structure, but the buffer layer 502 of the disclosure may have a multi-layer structure.

In the following description, for convenience, a structure in which the buffer layer 502 is a single layer is described.

A thin film transistor may be disposed on the buffer layer 502.

A passivation layer 506 may be disposed on the thin film transistor.

A planarization layer 509 may be disposed on the passivation layer 506.

The pixel electrode PE of the light emitting element ED may be disposed on a portion of an upper surface of the planarization layer 509.

The pixel electrode PE may be electrically connected to the thin film transistor through a contact hole provided in the planarization layer 509.

Although FIG. 5 illustrates a structure in which the pixel electrode PE is a single layer, the disclosure is not limited thereto. For example, the pixel electrode PE may have a multi-layer structure of two or more layers.

The pixel electrode PE may include a reflective electrode.

Specifically, when the pixel electrode PE has a single layer structure, the pixel electrode PE may be a reflective electrode including a reflective conductive material.

If the pixel electrode PE has a multi-layer structure, at least one layer may be a reflective electrode including a reflective conductive material. The other layers than the reflective electrode may be layers formed of a transparent conductive material.

A bank (not shown) may be disposed on a portion of the upper surface of the planarization layer 509.

The bank may define an emission area EA and a non-emission area NEA within the display area DA of the display device 100. For example, the area in which the bank is disposed in the display area DA may be a non-emission area NEA, and the area in which the bank is not disposed in the display area DA may be an emission area EA.

A light emitting layer EL of a light emitting element ED may be disposed on the pixel electrode PE.

Although FIG. 5 illustrates a structure in which the light emitting layer EL is a single layer, the disclosure is not limited thereto. The light emitting layer EL may be formed of a multi-layered organic layer.

The light emitting layer EL may emit light of at least one of red (R), green (G), and blue (B). However, the disclosure is not limited thereto, and the light emitting layer EL may emit other colors of light, such as white (W).

A common electrode CE of a light emitting element ED may be disposed on the substrate 500 on which the light emitting layer EL is disposed.

The common electrode CE may include a transparent conductive material or a semi-transmissive material.

Although FIG. 5 illustrates a structure in which the common electrode CE is a single layer, the disclosure is not limited thereto, and the common electrode CE may have a multi-layer structure of two or more layers.

Referring to FIG. 5, the display device 100 according to aspects of the disclosure may have a structure in which at least one thin film transistor is disposed in an emission area EA.

An encapsulation layer 530 may be disposed on the common electrode CE of the light emitting element ED.

The encapsulation layer 530 may include a first encapsulation layer 531 disposed on the common electrode CE, a second encapsulation layer 532 disposed on the first encapsulation layer 531, and a third encapsulation layer 533 disposed on the second encapsulation layer 532. The first and third encapsulation layers 531 and 533 may include an inorganic insulating material, and the second encapsulation layer 532 may include an organic insulating material.

The first and third encapsulation layers 531 and 533 including the inorganic insulating material may serve to prevent penetration of moisture and oxygen, and the second encapsulation layer 532 including the organic insulating material may serve to delay the movement of a small amount of moisture and oxygen permeated through the third encapsulation layer 533.

Although not illustrated, the encapsulation layer 530 may be disposed not only in the display area DA but also in the non-display area NDA of the display device 100.

At least one first insulation layer 540 may be disposed on the encapsulation layer 530.

A photochromic layer 550 and a light blocking layer (not shown) may be disposed on the first insulation layer 540.

A second insulation layer 545 may be disposed on the photochromic layer 550 and the light blocking layer.

A color filter layer 555 and a black matrix (not shown) may be disposed on the second insulation layer 545.

Referring to FIG. 5, the photochromic layer 550 and the color filter layer 555 may be disposed in the emission area EA in the display area DA. The light blocking layer and the black matrix may be disposed in the non-emission area NEA in the display area DA.

A cover window 570 may be disposed on the color filter layer 555 and the black matrix.

As such, the display device according to aspects of the disclosure may include at least one thin film transistor, and may include at least one storage capacitor Cst, although not illustrated in FIG. 5.

The structure of the thin film transistor and the storage capacitor according to aspects of the disclosure is described below in detail.

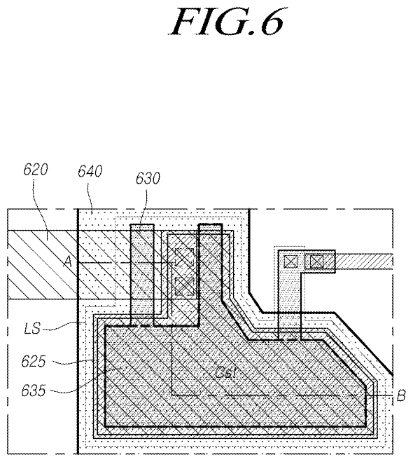

FIG. 6 is a plan view illustrating a pad area of a subpixel according to aspects of the disclosure.

Referring to FIG. 6, a subpixel according to aspects of the disclosure may include at least one thin film transistor and a storage capacitor Cst electrically connected to the thin film transistor. Here, the at least one thin film transistor may be a driving transistor DRT.

The storage capacitor Cst may include a light shield LS (a first storage capacitor electrode), a second storage capacitor electrode 625, a third storage capacitor electrode 635, and a fourth storage capacitor electrode 640.

Further, the driving transistor DRT may include an active layer 620, a gate electrode 630, and a metal layer 640. The metal layer 640 may be any one of the source electrode and the drain electrode of the driving transistor DRT.

Although not illustrated in FIG. 6, when the metal layer 640 is a source electrode, the driving transistor DRT may further include a drain electrode disposed on the same layer as the metal layer 640.

Referring to FIG. 6, the gate electrode 630 and the metal layer 640 may overlap with the channel area of the active layer 620.

Further, the metal layer 640 may contact the second storage capacitor electrode 625 to electrically connect the driving transistor DRT and the storage capacitor Cst.

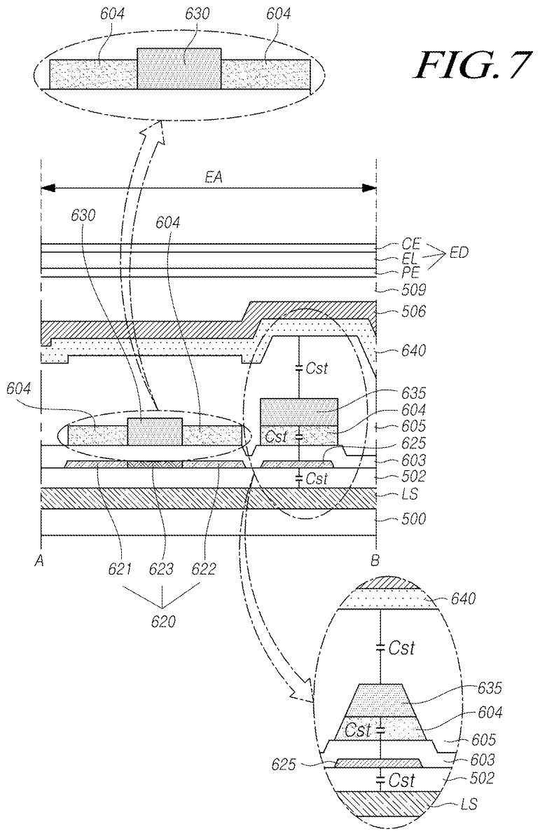

FIG. 7 is a cross-sectional view taken along line A-B of FIG. 6.

Referring to FIG. 7, a thin film transistor according to aspects of the disclosure may include a first active layer 620, a gate electrode 630, and a metal layer 640.

A storage capacitor according to aspects of the disclosure may include a first storage capacitor electrode LS, a second storage capacitor electrode 625, a third storage capacitor electrode 635, and a fourth storage capacitor electrode 640.

Specifically, referring to FIG. 7, a light shield LS may be disposed on the substrate 500.

FIG. 7 illustrates a structure in which the light shield LS is a single layer, but aspects of the disclosure are not limited thereto, and the light shield LS may be formed in a multilayer structure.

The light shield LS may include an opaque metal.

A buffer layer 502 may be disposed on the light shield LS.

At least one first active layer 620 and a second storage capacitor electrode 625 may be disposed on the buffer layer 502.

The first active layer 620 and the second storage capacitor electrode 625 may include an oxide semiconductor material. The oxide semiconductor material is a semiconductor material produced by controlling conductivity and adjusting the band gap through doping an oxide material, and may generally be a transparent semiconductor material having a wide band gap.

For example, each of the first active layer 620 and the second storage capacitor electrode 625 may include at least one of an indium gallium zinc oxide (IGZO), an indium tin oxide (ITO), a zinc oxide (ZnO), an indium gallium oxide (IGO), an indium zinc oxide (IZO), a cadmium oxide (CdO), an indium oxide (InO), a zinc tin oxide (ZTO), a zinc indium tin oxide (ZITO), an indium gallium zinc tin oxide (IGZTO), aluminum-doped zinc oxide (AZO), gallium-doped zinc oxide (GZO), antimony tin oxide (ATO), and fluorine-doped transparent oxides (FTO), but aspects of the disclosure are not limited thereto.

The first active layer 620 may include a first area 621, a second area 622, and a channel area 623 disposed between the first area 621 and the second area 622. The first area 621 and the second area 622 of the first active layer 620 may be conductive areas, and the channel area 623 may be non-conductive areas.

The second storage capacitor electrode 625 may be in a state in which an oxide semiconductor material has been rendered conductive.

Referring to FIG. 7, the light shield LS may overlap with the first active layer 620 and the second storage capacitor electrode 625.

The light shield LS may serve to prevent light from entering the channel area 623 of the first active layer 620 to deteriorate the characteristics of the thin film transistor. Further, the light shield LS may overlap with the second storage capacitor electrode 625 to serve as another storage capacitor electrode (e.g., the first storage capacitor electrode disposed under the second storage capacitor electrode 625).

A gate insulation film 603 may be disposed on the first active layer 620 and the second storage capacitor electrode 625.

The gate insulation film 603 may be formed of silicon oxide (SiOx) or the like.

A conductive auxiliary layer 604 may be disposed on the gate insulation film 603.

Referring to FIG. 7, the conductive auxiliary layer 604 may overlap with the first area 621 and the second area 622 of the first active layer 620. Further, the conductive auxiliary layer 604 may overlap with the second storage capacitor electrode 625.

The conductive auxiliary layer 604 may include hydrogen.

The conductive auxiliary layer 604 may serve to supply hydrogen to the first area 621 and the second area 622 of the first active layer 620 and the second storage capacitor electrode 625.

The charge amount of the thin film transistor including the oxide semiconductor may be determined by the hydrogen content relative to the composition of the metal included in the oxide semiconductor. Since hydrogen may act as a carrier in an oxide semiconductor, if the hydrogen content increases, the charge mobility may increase.

As described above, since hydrogen is supplied to the first area 621 and the second area 622 of the first active layer 620 and the second storage capacitor electrode 625 by the conductive auxiliary layer 604, electrical resistance of the first area 621, the second area 622, and the second storage capacitor electrode 625 may be decreased, and charge mobility may be enhanced.

The conductive auxiliary layer 604 may be an insulation film including nitride, and may be formed of, for example, silicon nitride (SiNx) or silicon oxynitride (SiON), but the material of the conductive auxiliary layer 604 according to aspects of the disclosure is not limited thereto.

As described above, as the conductive auxiliary layer 604 is disposed on the gate insulation film 603, a separate process for rendering a partial area of the first active layer 620 and the second storage capacitor 625 conductive may be omitted.

Referring to FIG. 7, a gate electrode 630 may be disposed on the gate insulation film 603.

As illustrated in FIG. 7, at least one end of the gate electrode 630 may contact one end of the conductive auxiliary layer 604.

The gate electrode 630 may be disposed to overlap with the channel area 623 of the first active layer 620. In other words, the gate insulation film 603 and the gate electrode 630 may be sequentially disposed on the channel area 623 of the first active layer 620.

The gate electrode 630 may have a property in which hydrogen is adsorbed, and thus, the gate electrode 630 may serve as a barrier that prevents hydrogen from being supplied to the channel area 623 of the first active layer 620.

The gate electrode 630 may include any one of metals such as aluminum (Al), gold (Au), silver (Ag), copper (Cu), tungsten (W), molybdenum (Mo), chromium (Cr), tantalum (Ta), titanium (Ti), and the like, or an alloy thereof. Specifically, the gate electrode 630 may include any one of titanium (Ti) and an alloy including titanium (Ti), but aspects of the disclosure are not limited thereto, and may include any material having high conductivity and capable of adsorbing hydrogen.

In other words, as the conductive auxiliary layer 604 is not disposed on the channel area 623 of the first active layer 620, but the gate electrode 630 having hydrogen adsorption properties is disposed, the first active layer 620 may have higher resistance than the first area 621 and the second area 622.

Referring to FIG. 7, the third storage capacitor electrode 635 may be disposed on the conductive auxiliary layer 604 and the gate insulation film 603 disposed on the second storage capacitor electrode 625.

The third storage capacitor electrode 635 may be formed through the same process as the gate electrode 630.

As illustrated in FIG. 7, as the conductive auxiliary layer 604 is disposed between the second storage capacitor electrode 625 and the third storage capacitor electrode 635, the dielectric constant is increased, and thus a high-efficiency storage capacitor Cst may be implemented.

Referring to FIG. 7, the inter-layer insulation film 605 may be disposed on the substrate 500 on which the gate insulation film 603, the conductive auxiliary layer 604, the gate electrode 630, and the third storage capacitor electrode 635 are disposed.

A metal layer 640 may be disposed on the inter-layer insulation film 605.

The metal layer 640 may be either the source electrode or the drain electrode of a thin film transistor.

Although not illustrated in FIG. 7, each of the source electrode and the drain electrode of the thin film transistor may be connected to either the first area 621 or the second area 622 of the first active layer 620. For example, when the source electrode is electrically connected to the first area 621, the drain electrode may be electrically connected to the second area 622.

As illustrated in FIG. 7, the metal layer 640 may overlap with the first active layer 620 and the first to third storage capacitor electrodes LS, 625, and 635.

The metal layer 640 may be disposed to overlap with the first active layer 620, thereby blocking light that may be incident on the first active layer 620.

For example, it is possible to prevent a change in the characteristics of the thin film transistor from occurring due to entry of the light emitted from the light emitting element ED disposed on the metal layer 640 to the thin film transistor. Accordingly, the reliability of the thin film transistor may be enhanced.

Further, the metal layer 640 may be utilized as a fourth storage capacitor electrode.

In other words, the storage capacitor Cst may include four storage capacitor electrodes, thereby increasing the capacity of the storage capacitor Cst without increasing the planar area occupied by the storage capacitor Cst.

The storage capacitor Cst may be applied to a display device requiring high resolution, fast response, and low power consumption.

As described above, as the capacity of the storage capacitor Cst disposed in the subpixel increases, even if the thickness of the insulation film disposed between the storage capacitor electrodes increases, it may be easy to drive the subpixel.

Referring to FIG. 7, an area where the patterned conductive auxiliary layer 604 and the third storage capacitor electrode 635 disposed on the conductive auxiliary layer 604 are disposed to overlap with each other may be present on the gate insulation film 603.

As two patterned components overlap with each other in the area in which the conductive auxiliary layer 604 and the third storage capacitor electrode 635 overlap with each other, a step may be higher than that of other areas.

Accordingly, a short circuit may occur between the third storage capacitor electrode 635 and the fourth storage capacitor electrode 640 (or a metal layer) disposed on the inter-layer insulation film 605.

As the storage capacitor Cst according to aspects of the disclosure includes the first to fourth storage capacitor electrodes LS, 625, 635, and 640, the capacity of the storage capacitor Cst increases. Thus, no problem arises in driving the subpixel even if the thickness of the inter-layer insulation film 605 is increased to prevent a short circuit between the third storage capacitor electrode 635 and the fourth storage capacitor electrode 640.

In other words, as the storage capacitor Cst according to aspects of the disclosure includes the first to fourth storage capacitor electrodes LS, 625, 635, and 640, it is possible to prevent a short circuit between the electrodes while maintaining an appropriate capacity for the storage capacitor Cst.

Referring to FIG. 7, a passivation layer 506 may be disposed on the metal layer 640.

A planarization layer 509 may be disposed on the passivation layer 506.

A light emitting element ED may be disposed on the planarization layer 509. The light emitting element ED may include a pixel electrode PE, a light emitting layer EL, and a common electrode CE.

Referring to FIG. 7, the at least one thin film transistor and the storage capacitor Cst disposed on the substrate 500 may be disposed in the emission area EA of the subpixel.

Since it is not necessary to reduce the area of the emission area EA to dispose the thin film transistor and the storage capacitor Cst, light emitting efficiency may be enhanced.

The light emitting element ED may be electrically connected to the thin film transistor disposed on the substrate 500, and may also be electrically connected to the storage capacitor Cst.

Specifically, the pixel electrode PE of the light emitting element ED may be electrically connected to the metal layer 640, and the metal layer 640 may be electrically connected to the storage capacitor Cst.

A structure in which the metal layer 640 and the storage capacitor Cst are electrically connected is described below in detail.

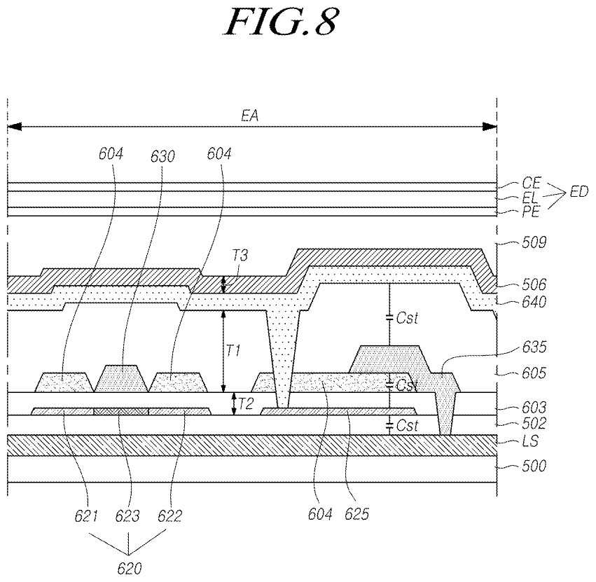

FIG. 8 is a cross-sectional view illustrating a structure in which a metal layer and a storage capacitor are connected according to aspects of the disclosure.

Referring to FIG. 8, the storage capacitor Cst may include a light shield LS which is a first storage capacitor electrode, a second storage capacitor electrode 625, a third storage capacitor electrode 635, and a metal layer 640 which is a fourth storage capacitor electrode.

Referring to FIG. 8, the third storage capacitor electrode 635 may contact the light shield LS, which is the first storage capacitor electrode.

Specifically, the third storage capacitor electrode 635 may contact a portion of the upper surface of the first storage capacitor electrode LS through a contact hole provided in the gate insulation film 603 and the buffer layer 502.

Referring to FIG. 8, the metal layer 640, which is the fourth storage capacitor electrode, may contact the second storage capacitor electrode 625.

Specifically, the metal layer 640, which is the fourth storage capacitor electrode, may contact a portion of the upper surface of the second storage capacitor electrode 625 through a contact hole provided in the inter-layer insulation film 605, the conductive auxiliary layer 604, and the gate insulation film 603.

Referring to FIG. 8, the thickness T1 of the inter-layer insulation film 605 may be larger than the thickness T2 of the gate insulation film 603 and the thickness T3 of the passivation layer 506.

As the thickness T1 of the inter-layer insulation film 605 is larger than the thickness T2 of the gate insulation film 603 and the thickness T3 of the passivation layer 506, the step coverage of the inter-layer insulation film 605 may be enhanced, and accordingly, the short circuit between the third storage capacitor electrode 635 and the metal layer 640, which is the fourth storage capacitor electrode, caused by the step between the conductive auxiliary layer 604 and the third storage capacitor electrode 635 may be avoided.

FIGS. 6 to 8 illustrate a structure in which the second storage capacitor electrode is a single layer, but aspects of the disclosure are not limited thereto.

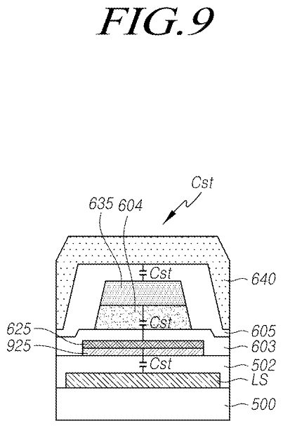

FIG. 9 is a cross-sectional view illustrating a structure of a storage capacitor according to aspects of the disclosure.

A storage capacitor Cst according to aspects of the disclosure may include a first storage capacitor electrode LS, a second storage capacitor electrode 625, a third storage capacitor electrode 635, and a fourth storage capacitor electrode 640.

Referring to FIG. 9, the second storage capacitor electrode 625 may be disposed on the active pattern 925 disposed on the buffer layer 502.

The active pattern 925 may include an oxide semiconductor material.

For example, the active pattern 925 may include at least one of an indium gallium zinc oxide (IGZO), an indium tin oxide (ITO), a zinc oxide (ZnO), an indium gallium oxide (IGO), an indium zinc oxide (IZO), a cadmium oxide (CdO), an indium oxide (InO), a zinc tin oxide (ZTO), a zinc indium tin oxide (ZITO), an indium gallium zinc tin oxide (IGZTO), aluminum-doped zinc oxide (AZO), gallium-doped zinc oxide (GZO), antimony tin oxide (ATO), and fluorine-doped transparent oxides (FTO), but aspects of the disclosure are not limited thereto.

The second storage capacitor electrode 625 disposed on the active pattern 925 may include metal.

For example, the second storage capacitor electrode 625 may include any one of metals such as aluminum (Al), gold (Au), silver (Ag), copper (Cu), tungsten (W), molybdenum (Mo), chromium (Cr), tantalum (Ta), titanium (Ti), or the like, or an alloy thereof. Specifically, the gate electrode 630 may include any one of titanium (Ti) and an alloy including titanium (Ti), but aspects of the disclosure are not limited thereto.

The second storage capacitor electrode 625 may include a conductive oxide including oxygen.

For example, the conductive oxide may include at least one of a transparent conductive oxide (TCO), a nitric oxide, an organic material, or the like. For example, the transparent conductive oxide (TCO) may include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO). The nitric oxide may include zinc oxynitride (ZnON) or the like.

A gate insulation film 603 may be disposed on the second storage capacitor electrode 625, and a conductive auxiliary layer 604 may be disposed on the gate insulation film 603.

Referring to FIG. 9, since the second storage capacitor electrode 625 is disposed under the conductive auxiliary layer 604, the active pattern 925 may not be rendered conductive.

Since hydrogen by the conductive auxiliary layer 604 is adsorbed to the second storage capacitor electrode 625, even if the conductive auxiliary layer 604 is disposed on the active pattern 925, the active pattern 925 may not be rendered conductive due to the second storage capacitor electrode 625 disposed between the active pattern 925 and the conductive auxiliary layer 604.

In FIGS. 7 to 9, a structure in which the conductive auxiliary layer 604 disposed on the active layer 620 is disposed on the same layer as the gate electrode 630 on the gate insulation film 603 and the conductive auxiliary layer 604 is disposed between the third storage capacitor electrode 635 and the gate insulation film 603 has been described, but the position of the conductive auxiliary layer 604 is not limited thereto.

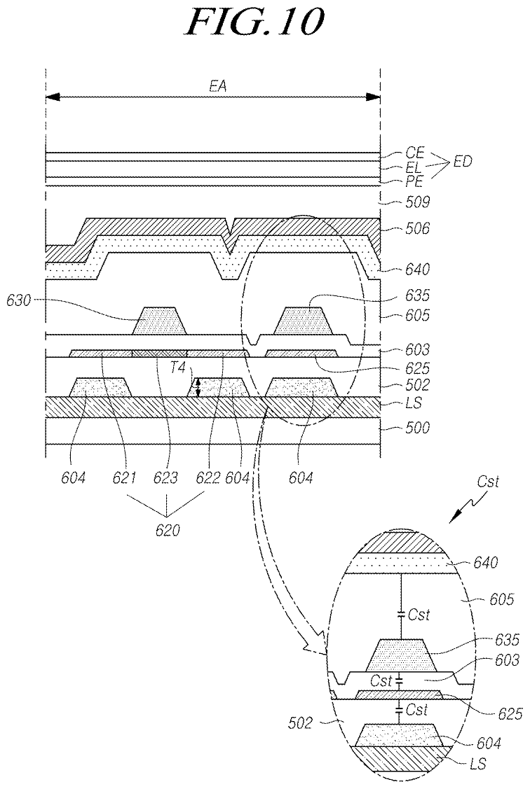

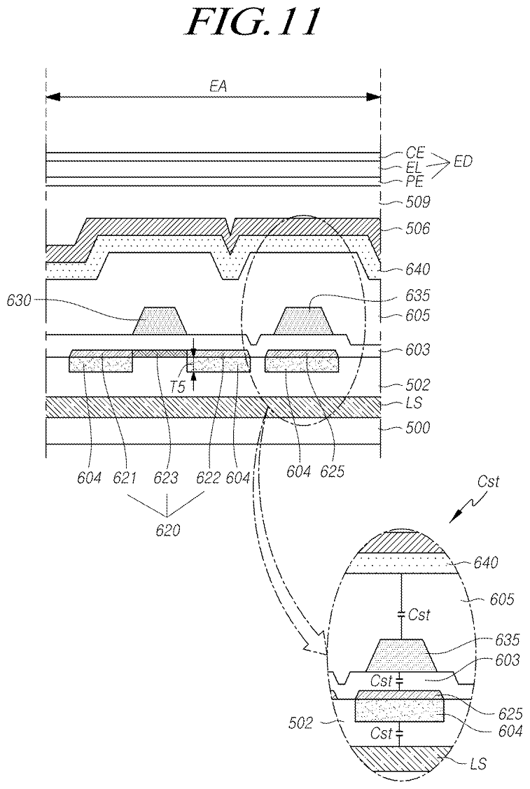

Various positions of the conductive auxiliary layer 604 according to aspects of the disclosure are described with reference to FIGS. 10 and 11.

FIGS. 10 and 11 are cross-sectional views illustrating various positions of a conductive auxiliary layer according to aspects of the disclosure.

First, referring to FIG. 10, the conductive auxiliary layer 604 may be disposed between the light shield LS and the buffer layer 502.

An active layer 620 and a second storage capacitor electrode 625 may be disposed on the buffer layer 502.

Referring to FIG. 10, the conductive auxiliary layer 604 may overlap with the first area 621 and the second area 622 of the active layer 620. Further, the conductive auxiliary layer 604 may overlap with the second storage capacitor electrode 625.

The first area 621 and the second area 622 of the active layer 620, and the second storage capacitor electrode 625 may be rendered conductive by supplying hydrogen by the conductive auxiliary layer 604.

Referring to FIG. 10, a gate insulation film 603 may be disposed on the active layer 620 and the second storage capacitor electrode 625.

A gate electrode 630 and a third storage capacitor electrode 635 may be disposed on the gate insulation film 603.

The gate electrode 630 may overlap with the channel area 623 of the active layer 620, and the third storage capacitor electrode 635 may overlap with the second storage capacitor electrode 625.

Referring to FIG. 10, the gate electrode 630 may not overlap with the conductive auxiliary layer 604, and the third storage capacitor electrode 635 may overlap with the conductive auxiliary layer 604.

Accordingly, the channel area 623 of the active layer 620 overlapping with the gate electrode 630 may not be rendered conductive by the conductive auxiliary layer 604, and the second storage capacitor electrode 625 overlapping with the third storage capacitor electrode 635 may be rendered conductive by the conductive auxiliary layer 604.

Referring to FIG. 11, the conductive auxiliary layer 604 may be disposed between the buffer layer 502 and the active layer 620 and between the buffer layer 502 and the second storage capacitor electrode 625.

In this case, the respective rear surfaces of the first area 621 and the second area 622 of the active layer 620 may contact the upper surface of the conductive auxiliary layer 604. Further, the rear surface of the second storage capacitor electrode 625 may contact the upper surface of the conductive auxiliary layer 604.

Although FIG. 11 illustrates a structure in which the conductive auxiliary layer 604 is disposed in the recess of the buffer layer 502, the structure according to aspects of the disclosure is not limited thereto, and any other structure may be possible in which the upper surface of the conductive auxiliary layer 604 contact one surface of each of the first area 621 and the second area 622 of the active layer 620, and the second storage capacitor electrode 625.

Referring to FIGS. 10 and 11, the thickness T4 of the conductive auxiliary layer 604 of FIG. 10 may be larger than the thickness T5 of the conductive auxiliary layer 604 of FIG. 11.

The conductive auxiliary layer 604 of FIG. 10 may be positioned farther away from the active layer 620 and the second storage capacitor electrode 625 than the conductive auxiliary layer 604 of FIG. 11.

Specifically, the conductive auxiliary layer 604 illustrated in FIG. 10 may be spaced apart from the active layer 620 and the second storage capacitor electrode 625 by the thickness of the buffer layer 502 on the conductive auxiliary layer 604. On the other hand, the conductive auxiliary layer 604 illustrated in FIG. 11 contacts the respective rear surfaces of a portion of the active layer 620 and the second storage capacitor electrodes 625.

The conductive auxiliary layer 604 contacting the respective rear surfaces of the portion of the active layer 620 and the second storage capacitor electrodes 625 may supply hydrogen more smoothly than the conductive auxiliary layer 604 spaced apart from the active layer 620 and the second storage capacitor electrode 625.

Accordingly, the closer the conductive auxiliary layer 604 is to the active layer 620 and the second storage capacitor electrode 625, the thinner the conductive auxiliary layer 604 may be. Conversely, as the conductive auxiliary layer 604 moves away from the active layer 620 and the second storage capacitor electrode 625, the thickness of the conductive auxiliary layer 604 may become larger.

As described above, the thickness may be adjusted according to the position of the conductive auxiliary layer 604 to smoothly supply hydrogen to the first area 621 and the second area 622 of the active layer 620, and the second storage capacitor electrode 625, so that the first area 621 and the second area 622 of the active layer 620, and the second storage capacitor electrode 625 may be rendered conductive.

In FIGS. 10 and 11, it has been described that the thickness of the conductive auxiliary layer 604 may be adjusted according to the distance between the conductive auxiliary layer 604 and the active layer 620, and the second storage capacitor electrode 625 with respect to the direction in which the light shield LS is stacked on the substrate 500, but the factor of varying the thickness of the conductive auxiliary layer 604 according to aspects of the disclosure is not limited thereto.

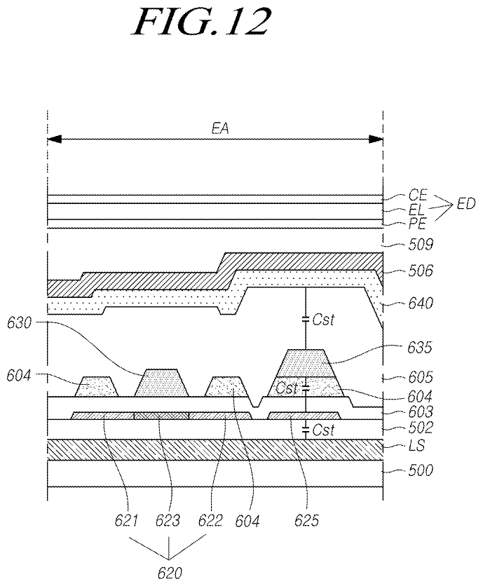

FIG. 12 is a view illustrating an arrangement relationship between a conductive auxiliary layer and a gate electrode according to aspects of the disclosure.

Referring to FIG. 12, the gate insulation film 603 may be disposed on the active layer 620 and the second storage capacitor electrode 625, and the gate electrode 630 and the conductive auxiliary layer 604 may be disposed on the gate insulation film 603.

Referring to FIG. 12, the conductive auxiliary layer 604 may be disposed on a portion of the first area 621 and a portion of the second area 622 of the active layer 620.

The conductive auxiliary layer 604 may not overlap with a portion of the first area 621 of the active layer 620 and may not overlap with a portion of the second area 622 of the active layer 620.

Further, the conductive auxiliary layer 604 may be disposed on the active layer 620 to be spaced apart from the gate electrode 630.

As the area in which the conductive auxiliary layer 604 does not overlap with the first area 621 and the second area 622 of the active layer 620 increases, the thickness of the conductive auxiliary layer 604 may increase.

In other words, as one side of the conductive auxiliary layer 604 adjacent to the gate electrode 630 moves away from one side of the gate electrode 630, the thickness of the conductive auxiliary layer 604 may increase, and as one side of the conductive auxiliary layer 604 adjacent to the gate electrode 630 moves closer to one side of the gate electrode 630, the thickness of the conductive auxiliary layer 604 may decrease.

Referring to FIG. 12, even if the conductive auxiliary layer 604 does not overlap with a portion of each of the first area 621 and the second area 622 of the active layer 620, as the thickness of the conductive auxiliary layer 604 increases, the amount of hydrogen diffused increases, so that the first area 621 and the second area 622 of the active layer 620 disposed in an area that does not overlap with the conductive auxiliary layer 604 may be overall rendered conductive.

On the other hand, unlike the first area 621 and the second area 622 of the active layer 620, the area of the active layer 620 overlapping with the gate electrode 630 may not be rendered conductive due to hydrogen adsorption by the gate electrode 630. Accordingly, the area (e.g., the channel area) of the active layer 620 overlapping with the gate electrode 630 may not be rendered conductive.

Further, the conductive auxiliary layer 604 disposed on the second storage capacitor electrode 625 may also overlap with the whole or only a portion of the second storage capacitor electrode 625.

Referring to FIGS. 7, 8, 9, 10, 11, and 12, the gate insulation film 603 may be disposed on the side surface and the upper surface of the active layer 620, and may be disposed on the side surface and the upper surface of the second storage capacitor electrode 625.

The gate insulation film 603 may be disposed on the substrate 500 in the remaining area except for the area in which the contact hole is formed. Accordingly, it is possible to prevent damage to the active layer 620 and the second storage capacitor electrode 625 formed of an oxide semiconductor material due to the patterning process of the gate insulation film 603.

Meanwhile, FIGS. 7, 8, 9, 10, 11, and 12 illustrate a structure in which the active layer 620 and the second storage capacitor electrode 625 are a single layer, but aspects of the disclosure are not limited thereto.

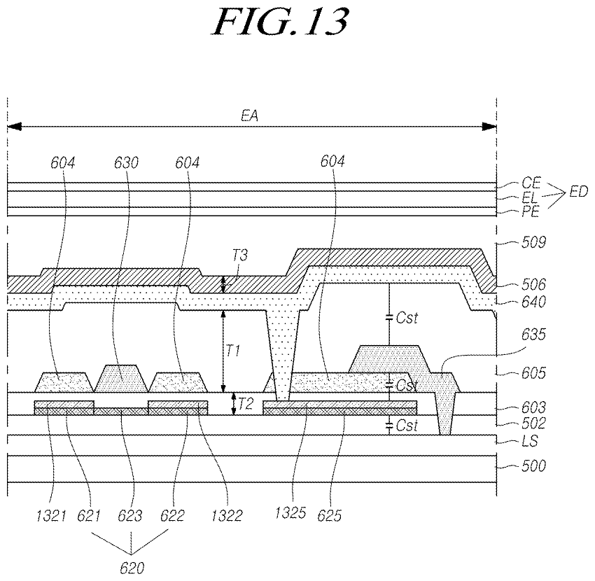

FIG. 13 is a view illustrating a transistor and a storage capacitor included in a display panel according to aspects of the disclosure.

Referring to FIG. 13, auxiliary electrodes 1321 and 1322 may be disposed on at least portions of the respective upper surfaces of the first area 621 and the second area 622 of the active layer 620.

Also, the auxiliary electrode 1325 may be disposed on the second storage capacitor electrode 625.

The auxiliary electrodes 1321, 1322, and 1325 may include a metal material. For example, the auxiliary electrodes 1321, 1322, and 1325 may include any one of metals such as molybdenum (Mo), titanium (Ti), aluminum (Al), gold (Au), silver (Ag), copper (Cu), or an alloy thereof, but aspects of the disclosure are not limited thereto.

For example, the auxiliary electrodes 1321, 1322, and 1325 may include a conductive oxide.

The conductive oxide may include at least one of a transparent conductive oxide (TCO), a nitric oxide, an organic material, or the like. For example, the transparent conductive oxide (TCO) may include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO). The nitric oxide may include zinc oxynitride (ZnON) or the like.

The active layer 620 and the second storage capacitor electrode 625 disposed under the auxiliary electrodes 1321, 1322, and 1325 may not be rendered conductive.

As described above, since the auxiliary electrodes 1321, 1322, and 1325 are disposed on at least a portion of the upper surface of the active layer 620 and at least a portion of the upper surface of the second storage capacitor electrode 625, electrical characteristics of the thin film transistor and the storage capacitor Cst may be enhanced.

Aspects of the disclosure described above are briefly described below.

Aspects of the disclosure may provide a display panel and a display device, comprising, a substrate 500, a first storage capacitor electrode LS disposed on the substrate 500, a buffer layer 502 disposed on the first storage capacitor electrode LS, an active layer 620 disposed on the buffer layer 502 and including a first area 621, a second area 622, and a channel area 623 disposed between the first area 621 and the second area 622, a gate insulation film 603 disposed on the active layer 620, a gate electrode 630 disposed on the gate insulation film 603 and overlapping with the channel area 623, an inter-layer insulation film 605 disposed on the gate electrode 630, and a metal layer 640 disposed on the inter-layer insulation film 605, wherein the first area 621 and the second area 622 of the active layer 620 are conductive areas, and wherein a conductive auxiliary layer 604 overlapping with at least a portion of each of the first area 621 and the second area 622 and not overlapping with the channel area 623 is included on the substrate 500.

Aspects of the disclosure may provide a display panel and a display device 20, comprising a first storage capacitor electrode LS disposed on a substrate 500, a buffer layer 502 disposed on the first storage capacitor electrode LS, an active layer 620 disposed on the buffer layer 502 and including a first area 621, a second area 622, and a channel area 623 disposed between the first area 621 and the second area 622, a gate insulation film 603 disposed on the active layer 620, a gate electrode 630 disposed on the gate insulation film 603 and overlapping with the channel area 623, an inter-layer insulation film 605 disposed on the gate electrode 630, and a metal layer 640 disposed on the inter-layer insulation film 605, wherein the first area 621 and the second area 622 of the active layer 620 are conductive areas, wherein a conductive auxiliary layer 604 overlapping with at least a portion of each of the first area 621 and the second area 622 is included on the substrate 500, and wherein the gate electrode 630 is disposed in an area between portions of the conductive auxiliary layer 604.

According to aspects of the disclosure, there may be provided a display panel and a display device capable of increasing the capacity of the storage capacitor while mitigating the step in the area where storage capacitor electrodes are disposed to prevent a short circuit, thereby saving costs and enhancing yield.

According to aspects of the disclosure, there may be provided a display panel and a display device capable of implementing high resolution, high response speed, and low power by increasing the capacity of the storage capacitor.

According to the aspects of the disclosure, there may be provided a display panel and a display device in which an electrode formed of an oxide semiconductor material and an active layer may easily be rendered conductive.

The above description has been presented to enable any person skilled in the art to make and use the technical idea of the disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the disclosure. The above description and the accompanying drawings provide an example of the technical idea of the disclosure for illustrative purposes only. Thus, it is intended that the present disclosure covers the modifications and variations of the aspects provided they come within the scope of the appended claims and their equivalents.

What is claimed:

1. A display panel, comprising:
a substrate;
a first storage capacitor electrode disposed on the substrate;
an active layer disposed on the first storage capacitor electrode and including a first area, a second area and a channel area disposed between the first area and the second area, wherein the first area and the second area of the active layer are conductive areas;
a gate electrode disposed on the active layer and overlapping with the channel area; and
a metal layer disposed on the gate electrode; and
a conductive auxiliary layer disposed on the substrate and overlapping with at least a portion of each of the first area and the second area and not overlapping with the channel area.

2. The display panel of claim 1, wherein the conductive auxiliary layer is disposed on the active layer, and
wherein the conductive auxiliary layer includes a first conductive auxiliary layer overlapping with the first area of the active layer and a second conductive auxiliary layer overlapping with the second area of the active layer.

3. The display panel of claim 2, wherein the gate electrode is disposed between the first conductive auxiliary layer and the second conductive auxiliary layer.

4. The display panel of claim 3, wherein one side surface of the conductive auxiliary layer contacts one side surface of the gate electrode.

5. The display panel of claim 3, wherein one side surface of the conductive auxiliary layer is spaced apart from one side surface of the gate electrode.

6. The display panel of claim 1, further comprising a buffer layer disposed between the first storage capacitor electrode and the active layer,
wherein the first storage capacitor electrode overlaps with the active layer, and
wherein the conductive auxiliary layer is disposed between the first storage capacitor electrode and the buffer layer.

7. The display panel of claim 1, further comprising a buffer layer disposed between the first storage capacitor electrode and the active layer,
wherein the conductive auxiliary layer is disposed between the buffer layer and the active layer.

8. The display panel of claim 7, wherein one surface of the conductive auxiliary layer contacts one surface of the first area of the active layer and one surface of the second area of the active layer.

9. The display panel of claim 1, wherein a thickness of the conductive auxiliary layer increases as a distance between the conductive auxiliary layer and the active layer increases.

10. The display panel of claim 1, further comprising:
a second storage capacitor electrode overlapping with the first storage capacitor electrode and disposed on the same layer as the active layer; and
a third storage capacitor electrode overlapping with the second storage capacitor electrode and disposed on the conductive auxiliary layer,
wherein the metal layer overlaps with the third storage capacitor electrode.

11. The display panel of claim 10, wherein the conductive auxiliary layer overlaps with at least a portion of the second storage capacitor electrode.

12. The display panel of claim 11, wherein the conductive auxiliary layer is disposed between the active layer and the third storage capacitor electrode.

13. The display panel of claim 11, further comprising a buffer layer disposed between the first storage capacitor electrode and the active layer,
wherein the conductive auxiliary layer is disposed between the first storage capacitor electrode and the buffer layer.

14. The display panel of claim 11, further comprising a buffer layer disposed between the first storage capacitor electrode and the active layer,
wherein the conductive auxiliary layer is disposed between the buffer layer and the second storage capacitor electrode.

15. The display panel of claim 14, wherein one surface of the conductive auxiliary layer contacts one surface of the second storage capacitor electrode.

16. The display panel of claim 10, wherein the metal layer is either a source electrode or a drain electrode of a thin film transistor,
wherein the metal layer is electrically connected to the second storage capacitor electrode, and
wherein the third storage capacitor electrode is electrically connected to the first storage capacitor electrode.

17. The display panel of claim 10, wherein a thickness of the conductive auxiliary layer increases as a distance between the conductive auxiliary layer and the second storage capacitor electrode increases.

18. The display panel of claim 10, further comprising a gate insulation film and an inter-layer insulation film,
wherein the gate insulation film is disposed between the second storage capacitor electrode and the third storage capacitor electrode,
wherein the inter-layer insulation film is disposed between the third storage capacitor electrode and the metal layer, and
wherein a thickness of the inter-layer insulation film is larger than a thickness of the gate insulation film.

19. The display panel of claim 1, wherein the conductive auxiliary layer includes silicon nitride (SiNx) or silicon oxynitride (SiON).

20. The display panel of claim 1, wherein the metal layer and the active layer overlap with each other.

21. The display panel of claim 1, wherein auxiliary electrodes are disposed on at least portions of respective upper surfaces of the first area and the second area of the active layer.

22. A display device, comprising:
a first storage capacitor electrode disposed on a substrate;
an active layer disposed on the first storage capacitor electrode and including a first area, a second area, and a channel area disposed between the first area and the second area, wherein the first area and the second area of the active layer are conductive areas;
a gate electrode disposed on the active layer and overlapping with the channel area;
a metal layer disposed on the gate electrode;
a conductive auxiliary layer overlapping with at least a portion of each of the first area and the second area is included on the substrate; and
wherein the gate electrode is disposed in an area between portions of the conductive auxiliary layer.

23. A display panel, comprising:
a substrate;
a thin film transistor disposed on the substrate, wherein the thin film transistor comprises an active layer, and the active layer comprises a first area, a second area, and a channel area disposed between the first area and the second area;
a light emitting element disposed on the thin film transistor;
at least one storage capacitor disposed on the substrate and electrically connected to the thin film transistor, wherein each of the at least one storage capacitor comprises a first storage capacitor electrode, a second storage capacitor electrode, a third storage capacitor electrode, and a fourth storage capacitor electrode stacked sequentially;
a conductive auxiliary layer disposed on the substrate, wherein the conductive auxiliary layer overlaps with the first area, the second area and the second storage capacitor electrode and does not overlap with the channel area,
wherein the light emitting element is electrically connected to the thin film transistor and at least one storage capacitor.

24. The display panel according to claim 23, wherein the thin film transistor further comprises a gate electrode and a fourth storage capacitor electrode, wherein the gate electrode and the fourth storage capacitor electrode overlap with the channel area.

25. The display panel according to claim 24, wherein the fourth storage capacitor electrode contacts the second storage capacitor electrode, and the third storage capacitor electrode contacts the first storage capacitor electrode.

26. The display panel according to claim 24, wherein the conductive auxiliary layer and the gate electrode are disposed on a same layer.

27. The display panel according to claim 23, wherein the at least one storage capacitor comprises multiple storage capacitors that are connected in parallel.
